(19) United States
(12) Patent Application Publication
(10) Pub. No.: US 2013/0038307 A1
(43) Pub. Date: Feb. 14, 2013

(54) SWITCHING CIRCUIT AND DC-TO-DC CONVERTER

(71) Applicants: Hiroshi SAITO, Tokyo (JP); Yuichi GOTO, Kanagawa-ken (JP); Kei KASAI, Tokyo (JP)

(72) Inventors: Hiroshi SAITO, Tokyo (JP); Yuichi GOTO, Kanagawa-ken (JP); Kei KASAI, Tokyo (JP)

(73) Assignee: KABUSHIKI KAISHA TOSHIBA, Tokyo (JP)

(21) Appl. No.: 13/416,057

(22) Filed: Mar. 9, 2012

(30) Foreign Application Priority Data
Aug. 8, 2011 (JP) 2011-173345

(51) Int. Cl. G05F 1/618; H03K 17/06

(52) U.S. Cl. 323/283; 327/109

(57) ABSTRACT

According to one embodiment, a switching circuit includes a high-side switch, a rectifier, and a driver. The high-side switch is connected between a high potential terminal and an output terminal. The rectifier is connected between the output terminal and a low potential terminal, and forward direction of the rectifier is the direction from the low potential terminal to the output terminal. The driver supplies a first voltage to a control terminal of the high-side switch in accordance with a high-side control signal and turns the high-side switch on. The driver supplies a second voltage being higher than the first voltage to the control terminal of the high-side switch when the voltage of the output terminal increases to not less than a predetermined value.

### CROSS-REFERENCE TO RELATED APPLICATIONS

This application is based upon and claims the benefit of priority from the prior Japanese Patent Application No. 2011-173345, filed on Aug. 8, 2011; the entire contents of which are incorporated herein by reference.

### FIELD

Embodiments described herein relate generally to a switching circuit and a DC-to-DC converter.

### BACKGROUND

Switching circuits constituted from a high-side switch and a low-side switch are widely used as output circuits that drive an inductive load. Also, in DC-to-DC converters using this type of switching circuit, for example, there is a demand for large current, so the ON-resistance of the switch devices is reduced by miniaturization using semiconductor processes. As a result, the recovery current flowing when the high-side switch is on is large, which causes switching noise and a reduction of operating efficiency.

### BRIEF DESCRIPTION OF THE DRAWINGS

FIG. 1 is a circuit diagram illustrating a configuration of a switching circuit according to a first embodiment;

FIG. 2 is a characteristic diagram showing a relationship between a voltage Vgs between a gate and a source, and an ON-resistance Ron;

FIGS. 3A to 3H are timing charts of main signals of a switching circuit according to the first embodiment, FIG. 3A shows a high-side control signal VH, FIG. 3B shows a low-side control signal VL, FIG. 3C shows a detection signal VD, FIG. 3D shows a voltage VG of a control terminal, FIG. 3E shows an output voltage VLX, FIG. 3F shows a high-side current IH, FIG. 3G shows a low-side current IL, and FIG. 3H shows a load current ILL;

FIG. 4 is another circuit diagram illustrating a configuration of a high-side controller of a driver;

FIG. 5 is a circuit diagram illustrating a configuration of a switching circuit according to a second embodiment;

FIG. 6 is a circuit diagram illustrating a configuration of a switching circuit according to a third embodiment; and

FIG. 7 is a circuit diagram illustrating a DC-to-DC converter according to a fourth embodiment.

### DETAILED DESCRIPTION

In general, according to one embodiment, a switching circuit includes a high-side switch, a rectifier, and a driver. The high-side switch is connected between a high potential terminal and an output terminal. The rectifier is connected between the output terminal and a low potential terminal, and forward direction of the rectifier is the direction from the low potential terminal to the output terminal. The driver supplies a first voltage to a control terminal of the high-side switch in accordance with a high-side control signal and turns the high-side switch on. The driver supplies a second voltage being higher than the first voltage to the control terminal of the high-side switch when the voltage of the output terminal increases to not less than a predetermined value.

Hereinbelow, embodiments are described with reference to the drawings. In the following description, identical components are marked with the same reference numerals, and a description of components once described is omitted as appropriate. The embodiments described below can be appropriately combined.

First, a first embodiment is explained.

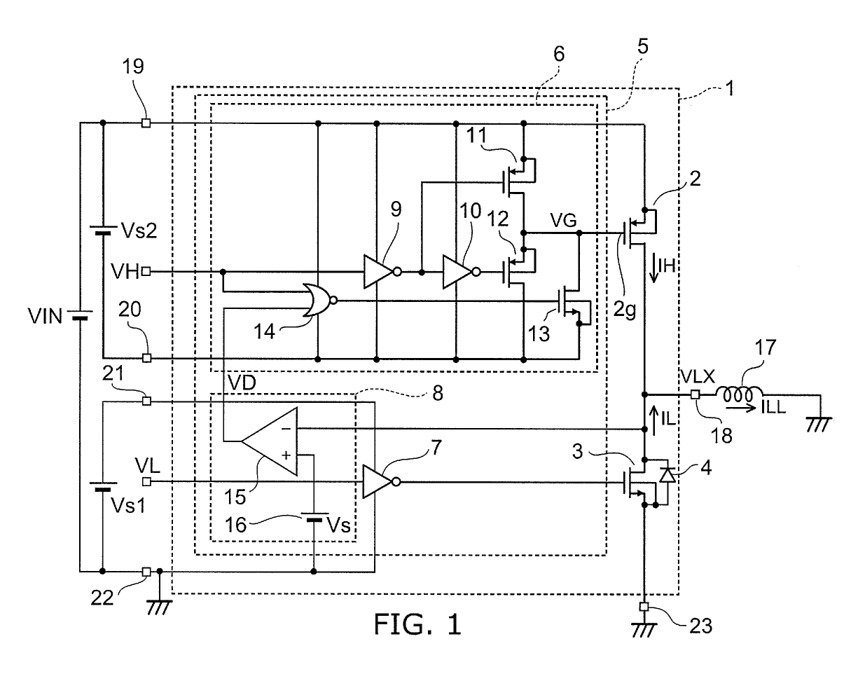

FIG. 1 is a circuit diagram illustrating a configuration of a switching circuit according to the first embodiment.

The switching circuit (the section enclosed by the broken line 1) includes a high-side switch 2 and a low-side switch 3 connected in series, and a driver (the section enclosed by the broken line 5) that controls the high-side switch 2 and the low-side switch 3, and the switching circuit drives an inductive load 17. The low-side switch 3 includes a rectifier 4 as a parasitic diode.

The high-side switch 2 is connected between an output terminal 18 and a high potential terminal 19. The high-side switch 2 is a P-channel MOSFET (hereafter referred to as PMOS), whose source as first main electrode is connected to the high potential terminal 19, and whose drain as second main electrode is connected to the output terminal 18. Also, a gate 2g as control terminal of the high-side switch 2 is connected to the driver 5. The high-side switch 2 includes a parasitic diode which is not illustrated on the drawings.

The low-side switch 3 is connected between the output terminal 18 and a low potential terminal 23. The low-side switch 3 is an N-channel MOSFET (hereafter referred to as NMOS), whose source as first main electrode is connected to the low potential terminal 23, and whose drain as second main electrode is connected to the output terminal 18. Also, a gate as control terminal of the low-side switch 3 is connected to the driver 5. The low potential terminal 23 is grounded, and a power supply voltage VIN is supplied between the high potential terminal 19 and the low potential terminal 23.

The rectifier 4 is connected between the output terminal 18 and the low potential terminal 23, with the direction from the low potential terminal 23 to the output terminal 18 being a forward direction. In other words, the anode as first main electrode of the rectifier 4 is connected to the low potential terminal 23, and the cathode as second main electrode of the rectifier 4 is connected to the output terminal 18.

The driver 5 includes a high-side controller 6 that controls the high-side switch 2, a low-side controller 7 that controls the low-side switch 3, and a detector 8 that detects the voltage of the output terminal 18, i.e. the output voltage VLX.

The high-side controller 6 is connected between the high potential terminal 19 and a second intermediate potential terminal 20, and supplies a voltage VG to a control terminal 2g of the high-side switch 2 to control the high-side switch 2 in accordance with a high-side control signal VH. The high-side controller 6 includes NOT circuits (inverters) 9, 10, a first transistor 11, a second transistor 12, a third transistor 13, and a NOR circuit 14.

The first transistor 11 and the second transistor 12 are connected in series between the high potential terminal 19 and the second intermediate potential terminal 20. The first transistor 11 is a PMOS, an high-side control signal VH inverted via the inverter 9 is input to the gate. The second transistor 12 is a PMOS, and a signal in phase with the high-side control signal VH is input to the gate via the inverters 9, 10. The source of the first transistor 11 is connected to the high potential terminal 19, and the drain of the first transistor 11 is connected to the source of the second transistor 12, and the drain of the second transistor 12 is connected to the second intermediate potential terminal 20.

Also, the third transistor 13 is connected in parallel with the second transistor 12. The third transistor 13 is an NMOS, whose drain is connected to the source of the second transistor 12, and the source of the third transistor 13 is connected to the drain of the second transistor 12 and the second intermediate potential terminal 20. The inverted signal of the logical sum of the high-side control signal VH and the output of the detector 8 is input to the gate of the third transistor 13 via the NOR 14. A power supply voltage Vs2 is supplied between the high potential terminal 19 and the second intermediate potential terminal 20, and the inverters 9, 10 are operated with the power supply voltage Vs2. The power supply voltage Vs2 is not greater than the power supply voltage VIN.

The low-side controller 7 is connected between a first intermediate potential terminal 21 and a ground terminal 22, and outputs a signal that is an inverted low-side control signal VL to the gate as a control terminal of the low-side switch 3. A power supply voltage Vs1 is supplied between the first intermediate potential terminal 21 and the ground terminal 22, and the ground terminal 22 is grounded together with the low potential terminal 23. Also, the low-side controller 7 is an inverter, and the low-side controller 7 is operated with the power supply voltage Vs1. The power supply voltage Vs1 is not greater than the power supply voltage VIN.

The detector 8 includes a comparison circuit 15 that compares the output voltage VLX with a reference Vs, and a power supply circuit 16 that generates the reference voltage Vs. An inverting input terminal of the comparison circuit 15 is connected to the output terminal 18, and the reference voltage Vs output from the power supply circuit 16 is input to a non-inverting input terminal. A detection signal VD is output from the output terminal of the comparison circuit 15 to the NOR 14 as the output of the detector 8. A level shifter that replaces the logic level of the detection signal VD with the logic level of the high-side controller 6 is omitted. Also, the reference voltage Vs is a voltage that is a standard for detecting that the output voltage VLX has increased relative to the voltage of the low potential terminal 23, and is set to, for example, 90% of the power supply voltage VIN.

Next, the operation of the switching circuit 1 is explained.

The switching circuit 1 controls a current ILL flowing in the inductive load 17 by alternately switching on the high-side switch 2 and the low-side switch 3, in accordance with the externally input high-side control signal VH and the low-side control signal VL. Also, the high-side controller 6 of the driver 5 controls the ON-resistance Ron of the high-side switch 2 by switching the voltage VG supplied to the control terminal 2g of the high-side switch 2 in accordance with the level of the output voltage VLX detected by the detector 8.

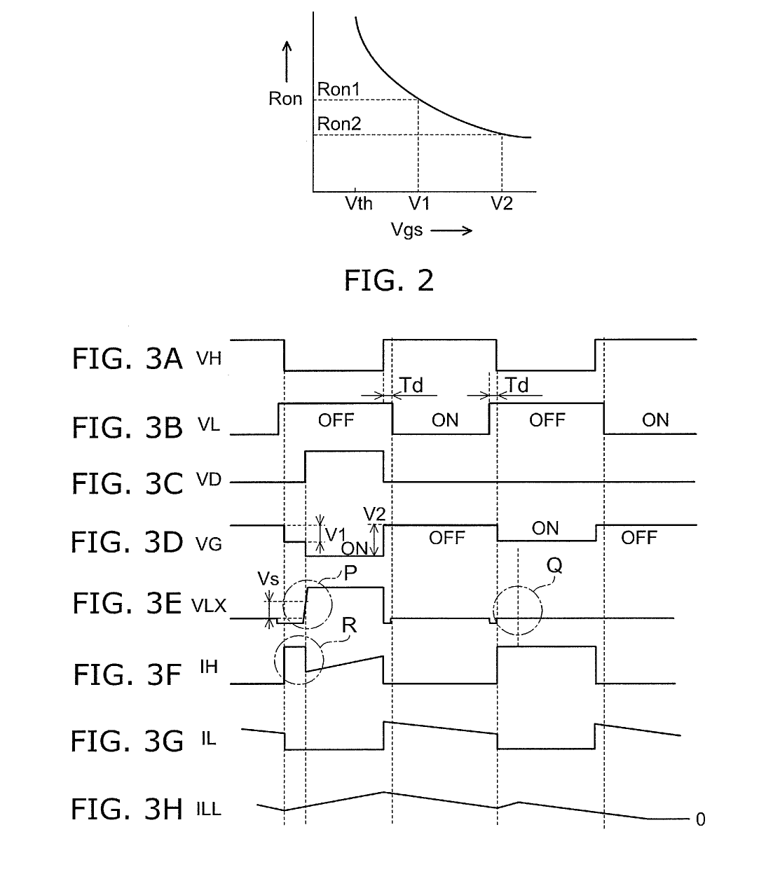

FIG. 2 is a characteristic diagram showing a relationship between a voltage Vgs between a gate and a source, and an ON-resistance Ron.

In FIG. 2, the horizontal axis is the voltage Vgs between the gate and the source of the high-side switch 2, and the vertical axis is the ON-resistance Ron, and the dependence of the ON-resistance Ron on the voltage Vgs between the gate and the source is shown. Each voltage is expressed as an absolute value.

The ON-resistance Ron reduces monotonically with respect to the voltage Vgs between the gate and the source that is not less than a threshold value of voltage Vth. The voltage VG of the control terminal 2g has the electric potential of the high potential terminal 19 as standard, so the voltage VG of the control terminal 2g is equal to the voltage Vgs between the gate and the source of the high-side switch 3. When the voltage VG of the control terminal 2g is a first voltage V1, the ON-resistance is Ron1. When the voltage of the control terminal 2g is a second voltage V2, the ON-resistance is Ron2. Here, |Vgs1|<|Vgs2|, and Ron1>Ron2.

FIGS. 3A to 3H are timing charts of the main signals of the switching circuit according to the first embodiment, FIG. 3A shows the high-side control signal VH, FIG. 3B shows the low-side control signal VL, FIG. 3C shows the detection signal VD, FIG. 3D shows the voltage VG of the control terminal, FIG. 3E shows the output voltage VLX, FIG. 3F shows the high-side current IH, FIG. 3G shows the low-side current IL, and FIG. 3H shows the load current ILL.

FIG. 3A shows the high-side control signal VH for a case that a rectangular wave that periodically repeats a high level and a low level is input. Also, the low-side control signal VL is a signal with the opposite phase to the high-side control signal VH (FIG. 3B).

Also, FIG. 3B indicates whether the low-side switch 3 is controlled to be ON or OFF by ON and OFF respectively, and FIG. 3D indicates whether the high-side switch 2 is controlled to be on or off by ON and OFF respectively. Also, a dead time Td is provided to avoid the high-side switch 2 and the low-side switch 3 from both being ON at the same time.

First, the operation when the externally input high-side control signal VH is high level, and the low-side control signal VL is low level is explained (FIGS, 3A, 3B).

The high level high-side control signal VH is input to the NOR 14 of the high-side controller 6, and low level is output to the gate of the third transistor 13. As a result, the third transistor 13 is off. Also, the high level high-side control signal VH is input to the inverter 9, and low level is output to the gate of the first transistor 11. As a result, the first transistor 11 is on. Also, the inverter 10 outputs high level to the gate of the second transistor 12. As a result the second transistor 12 is off. Therefore, the first transistor 11 that is turned on makes the voltage VG of the control terminal 2g of the high-side switch 2 high level. As a result, the high-side switch 2 is off, and the high-side current IH does not flow (FIGS. 3D, 3F).

The low level low-side control signal VL is input to the low-side controller 7, and high level is output to the gate of the low-side switch 3. As a result, the low-side switch 3 is on. The inductive load 17 makes the output voltage VLX low level (FIG. 3E), and causes a regenerated current to flow via the low-side switch 3. The low-side current IL flowing in the low-side switch 3 flows as the load current ILL (FIG. 3G). The output voltage VLX is lower than the reference voltage Vs, so the detector 8 outputs high level as the detection signal VD (FIG. 3C).

Next, the operation in the dead time Td in which the high-side control signal VH is high level and the low-side control signal VL is high level is explained.

When the low-side control signal VL changes to high level, the low-side controller 7 outputs low level to the gate of the low-side switch 3. As a result, the low-side switch 3 is off. Inductive load 17 causes a regenerated current to flow via the rectifier (parasitic diode) 4 of the low-side switch 3. The load current ILL flows through the rectifier 4 of the low-side switch 3 as the low-side current IL (FIGS. 3G, 3H).

Next, the operation when the high-side control signal VH is changed to low level and the low-side control signal VL is changed to high level is explained (FIGS. 3A, 3B).

The low level high-side control signal VH is input to the inverter 9, and high level is output to the gate of the first transistor 11. As a result, the first transistor 11 is off. Also, the inverter 10 outputs low level to the gate of the second transistor 12. As a result, the second transistor 12 is on. The voltage between the source and the drain of the second transistor 12 is almost equal to the voltage Vsg between the source and the gate of the second transistor 12 (voltage in the opposite direction to the voltage Vgs between the gate and the source).

Therefore, the high-side controller 6 of the driver 5 outputs a first voltage V1=Vs2−Vsg, as the voltage VG of the control terminal 2g of the high-side switch 2. In a PMOS, the gate potential is lower than the source potential, therefore, the first voltage V1 is directed so that the gate-source voltage of the high-side switch 2 is positive with the gate of the high-side switch 2 being the reference potential.

The low-side controller 7 outputs low level to the gate of the low-side switch 3. As a result, the low-side switch 3 is maintained in the off state. Also, the high-side switch 2 is on, so the regenerated current that flowed in the low-side switch 3 flows through the high-side switch 2 as the rectifier 4 reverse direction recovery current. Therefore, during the reverse direction recovery time of the rectifier 4, the large current value of the high-side current IH of the reverse direction recovery current flows in the high-side switch 2 (the portion enclosed with the dashed line R in FIG. 3F). However, the relatively low first voltage V1 is supplied to the voltage VG of the control terminal 2g of the high-side switch 2, so the high-side current IH is restricted by the relatively large ON-resistance Ron1 of the high-side switch 2.

During the period that the reverse direction recovery current is flowing in the high-side switch 2, the output voltage VLX is low level (FIG. 3E). The output voltage VLX is lower than the reference voltage Vs of the power supply circuit 16, so the detector 8 outputs high level as the detection signal VD. As a result, the NOR 14 outputs low level to the gate of the third transistor 13, so the third transistor 13 is off.

If the output terminal 18 is not short circuited, after the reverse direction recovery time of the rectifier 4, the high-side switch 2 raises the output voltage VLX from low level to high level (the portion enclosed in the dashed line P in FIG. 3E). Also, if the output terminal 18 is short circuited, after the reverse direction recovery time of the rectifier 4, the high-side switch 2 cannot raise the output voltage VLX to high level, so the output voltage VLX remains at low level (the portion enclosed in the dashed line Q in FIG. 3E).

First, (1) the case where the output terminal 18 is not short circuited is explained, then (2) the case where the output terminal 18 is short circuited is explained.

(1) When the output terminal is not short circuited, as described above, the high-side switch 2 raises the output voltage VLX from low level to high level (the portion enclosed in the dashed line P in FIG. 3E). As a result, the output voltage detector 8 detects that the output voltage VLX has been raised to not less than the reference voltage Vs, and low level is output as the detection signal VD (FIG. 3C).

The low level detection signal VD is input to the NOR 14, and high level is output to the gate of the third transistor 13. As a result, the third transistor 13 is turned on, and the output voltage VG of the control terminal 2g of the high-side switch 2 becomes the second voltage V2 which is higher than the first voltage V1 (FIG. 3D). As a result, the ON-resistance Ron of the high-side switch 2 becomes the ON-resistance Ron2 which is lower than when the first voltage V1 was supplied to the gate. And, similarly to the first voltage V1, the second voltage V2 is directed so that gate-source voltage of high-side switch 2 becomes positive with the gate of the high-side switch 2 being the reference. Also, the second voltage V2 is almost equal to the voltage Vs2 between the high potential terminal 19 and the second intermediate potential terminal 20.

Then, with the ON-resistance Ron in a relatively low state, the high-side switch 2 raises the output voltage VLX up to almost the power supply voltage VIN. As a result, while the high-side control signal VH is low level, direct current voltage is supplied to both ends of the inductive load 17, and the high-side current IH increases linearly (FIG. 3F). Also, the high-side current IH flows as the load current ILL through the inductive load 17 via the output terminal 18.

Next, the operation in the dead time Td when the high-side control signal VH is high level and the low-side control signal VL is high level is the same as described above. The high-side control signal VH that has been changed to high level is input to the high-side controller 6, and the high-side controller 6 outputs high level as the voltage VG of the control terminal 2g of the high-side switch 2. As a result the high-side switch 2 is off. Also, the high level low-side control signal VL is input to the low-side controller 7, and the low-side controller 7 outputs low level to the gate of the low-side switch 3. As a result, the low-side switch 3 is maintained in the off state. The inductive load 17 causes a regenerated current to flow via the rectifier 4 of the low-side switch 3. The load current ILL flows through the rectifier 4 of the low-side switch 3 as the low-side current IL (FIGS. 3G, 3H).

Then, when the high-side control signal VH changes to high level and the low-side control signal VL changes to low level, the next cycle starts, and the operation as described above is repeated.

(2) When the output terminal 18 is short circuited, as described above, the output voltage VLX remains at low level (the portion enclosed in the dashed line Q in FIG. 3E). The detector 8 detects that the output voltage VLX is lower than the reference voltage Vs, and outputs high level as the detection voltage VD (FIG. 3C).

The NOR 14 continues to output low level to the gate of the third transistor 13, because the detection signal VD is high level. As a result, the third transistor 13 remains off, and the voltage VG of the control terminal 2g of the high-side switch 2 is maintained at the first voltage V1 (FIG. 3D). As a result, the ON-resistance of the high-side switch 2 remains in a relatively high state. Although the output terminal 18 is short circuited, the current IH of the high-side switch 2 is a restricted current value due to the relatively high ON-resistance.

Next, the operation in the dead time Td when the high-side control signal VH is high level and the low-side control signal VL is high level is the same as described above. The high-side control signal VH which has changed to high level is input to the high-side controller 6, and the high-side controller 6 outputs high level as the voltage VG of the control terminal 2g of the high-side switch 2. As a result, the high-side switch 2 is off. Also, the high level low-side control signal VL is input to the low-side controller 7, and the low-side controller 7 outputs low level to the gate of the low-side switch 3. As a result, the low-side switch 3 is maintained in the off state.

The inductive load 17 causes a regenerated current to flow via the rectifier 4 of the low-side switch 3. The load current ILL flows through the rectifier 4 of the low-side switch 3 as the low-side current IL (FIGS. 3G, 3H).

Then, when the high-side control signal VH changes to high level and the low-side control signal VL changes to low level, the next cycle starts, and the operation as described above is repeated.

Next, the effect of this embodiment will be explained.

In this embodiment, when the high-side control signal VH is changed to low level, the first voltage V1, which is a relatively low voltage, is supplied to the control terminal 2g, and the high-side switch 2 is turned on. As a result, the high-side switch 2 is on with the ON-resistance in a relatively high state, so it is possible to limit the current value of the reverse direction recovery current, and it is possible to reduce noise and electromagnetic radiation by a pulse-like flow through current between the high-side switch 2 and the low-side switch 3.

Also, in this embodiment, after the first voltage V1 is supplied to the control terminal 2g of the high-side switch 2 and the high-side switch 2 is turned on, when the output voltage VLX has been raised to not less than the reference voltage Vs, the second voltage V2 which is higher than the first voltage V1 is supplied to the control terminal 2g. As a result, even if the value of the rectifier 4 reverse direction recovery time and the value of the power supply voltage VIN input vary, it is possible to reliably detect the time of termination of the reverse direction regenerated current flowing through the high-side switch 2. For example, the ON-resistance of the high-side switch 2 varies due to errors or variation in the first voltage V1, so the current value flowing through the high-side switch 2 when the first voltage V1 is supplied can vary. However, in this embodiment, it is possible to reliably detect the time of termination of the reverse direction regenerated current flowing through the high-side switch 2.

Also, in this embodiment, after the first voltage V1 is supplied to the control terminal 2g of the high-side switch 2 and the high-side switch 2 is turned on, the second voltage V2, which is higher than the first voltage V1, is supplied to the control terminal 2g, so the high-side switch 2 is in a state with a relatively low ON-resistance. As a result, it is possible to reduce the conduction loss of the high-side switch 2. The time that the first voltage V1 is supplied is almost the same as the reverse direction recovery time of the rectifier 4 of the low-side switch 2, and is short compared with the switching period of the switching circuit 1. Therefore, electrical power losses are small due to the relatively high ON-resistance when the first voltage V1 is supplied.

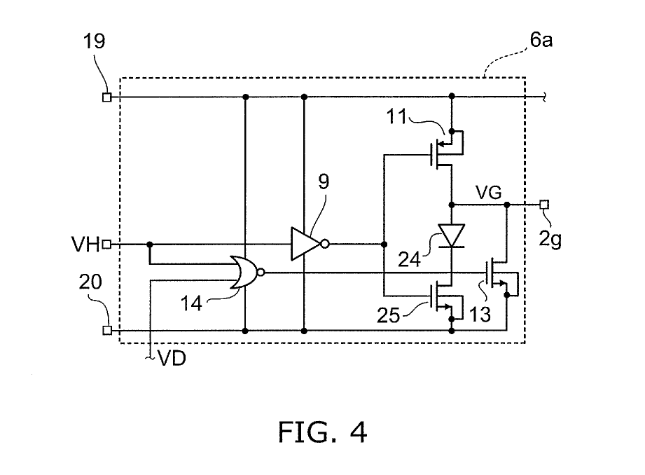

FIG. 4 is another circuit diagram illustrating a configuration of a high-side controller of a driver.

As illustrated in FIG. 4, a high-side controller 6a differs in the configuration of the second transistor 12 that outputs the first voltage V1 and the inverter 10, compared with the high-side controller 6 illustrated in FIG. 1. In other words, the inverter 10 and the second transistor 12 are replaced by a diode 24 and a second transistor 25. The inverter 9, the first transistor 11, the third transistor 13, and the NOR 14 are the same as in the high-side controller 6. In FIG. 4, elements that are the same as in FIG. 1 are given the same reference numerals.

The first transistor 11, the diode 24, and the second transistor 25 are connected in series between the high potential terminal 19 and the second intermediate potential terminal 20. A signal that is the high-side control signal VH inverted via the inverter 9 is input to the gate of the second transistor 25. The third transistor 13 is connected to the two ends of the diode 24 and the second transistor 25, which are connected in series.

When the high-side control signal VH is changed to low level, high level is input to the gate of the second transistor 25 via the inverter 9. As a result, the second transistor 25 is turned on, and the first voltage V1=Vs2−Vf=V2−Vf is output as the voltage VG of the control terminal 2g of the high-side switch 2. Here, Vf is the forward direction voltage of the diode 24.

In this way, the high-side controller 6a differs from the high-side controller 6 in that the high-side controller 6a outputs a voltage as the first voltage V1 which is lower than the second voltage V2 by the forward direction voltage Vf of the diode 24, whereas the high-side controller 6 outputs a voltage which is lower by Vsg between the source and gate of the second transistor 12 of the PMOS. In FIG. 4, an example is illustrated in which there is one diode 24, but an arbitrary number of diodes may be connected in a series in accordance with the value of the first voltage V1.

The rest of the configuration, operation, and effect are the same as those of the high-side controller 6, and the configuration, operation, and effect of a switching circuit constituted from the high-side controller 6a instead of the high-side controller 6 are the same as described for the first embodiment.

Next a second embodiment will be described.

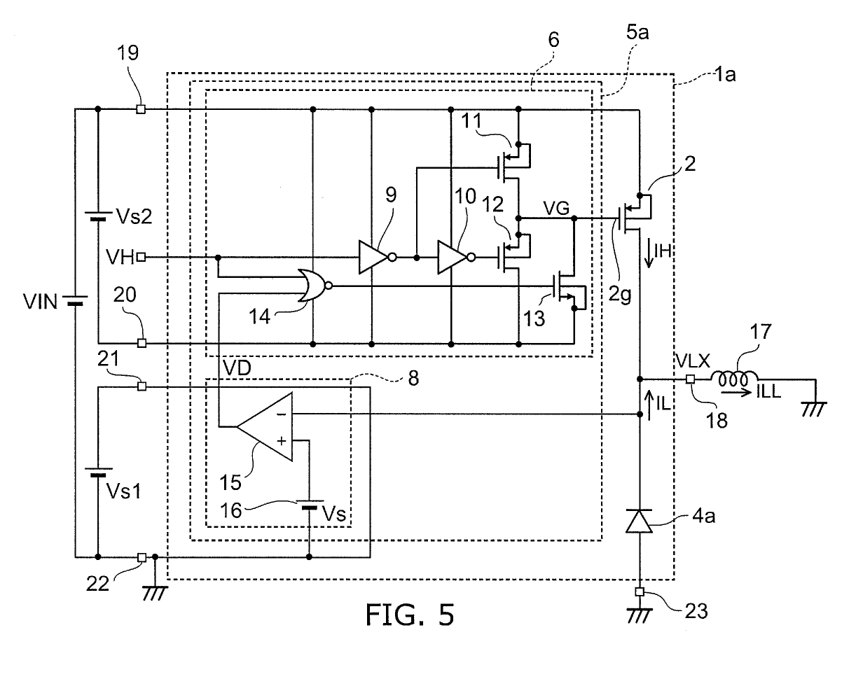

FIG. 5 is a circuit diagram illustrating a configuration of a switching circuit according to the second embodiment.

As illustrated in FIG. 5, a switching circuit la differs from the switching circuit 1 illustrated in FIG. 1 in that the switching circuit la does not include the low-side switch 3 and the low-side controller 7, and the rectifier 4 is constituted by a diode 4a. Therefore, there is no low-side control signal VL, and the low-side current IL is the current IL of the rectifier 4. In FIG. 5, elements that are the same as in FIG. 1 are given the same reference numeral.

The configuration, operation, and effect of this embodiment apart from the above is the same as those of the first embodiment as described above.

Next, a third embodiment will be explained.

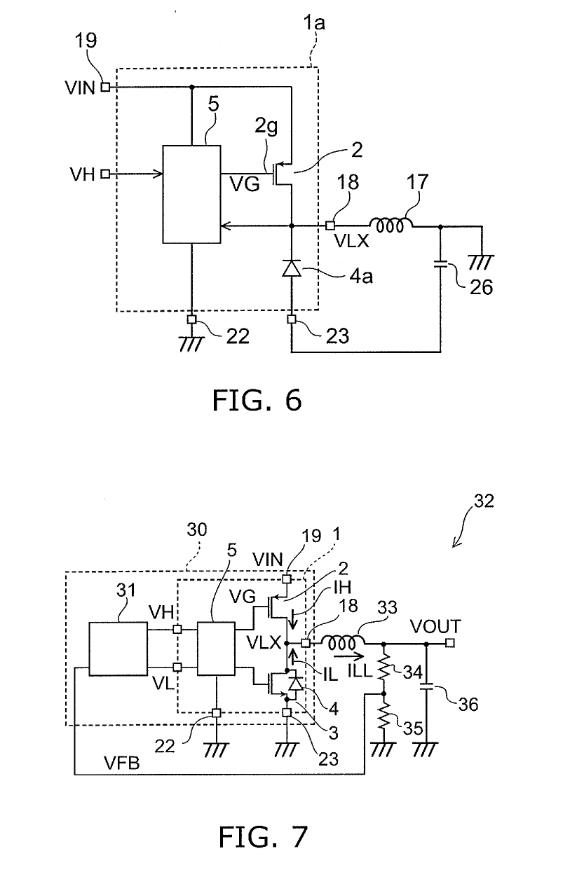

FIG. 6 is a circuit diagram illustrating a configuration of a switching circuit according to the third embodiment.

As illustrated in FIG. 6, a switching circuit 1b differs from the switching circuit la illustrated in FIG. 5 in that the low potential terminal 23 is grounded via a smoothing capacitor, and negative voltage is generated at the low potential terminal 23. In FIG. 6, the second intermediate potential terminal 20 and the first intermediate potential terminal 21 are omitted. Also, elements that are the same as FIG. 5 are given the same reference numerals.

In this embodiment, after the first voltage V1 is supplied to the control terminal 2g of the high-side switch 2 and the high-side switch 2 is turned on, when the output voltage VLX has raised to not less than the reference voltage Vs, the second voltage V2 which is higher than the first voltage V1 is supplied to the control terminal 2g. However, the low potential power supply terminal 23 is at a negative voltage, so immediately after the high-side switch 2 is turned on, the output voltage VLX becomes a negative voltage. However, the reference voltage Vs is a positive voltage the same as in the first embodiment as described above, for example, set to 90% of the power supply voltage VIN.

Therefore, the configuration, operation, and effect of this embodiment apart from this are the same as the second embodiment which has no low-side switch 3 and low-side controller 7.

FIG. 7 is a circuit diagram illustrating a DC-to-DC converter according to a fourth embodiment.

As illustrated in FIG. 7, a DC-to-DC converter 30 includes the switching circuit 1, and a controller 31 that controls the switching circuit 1. The switching circuit 1 is the same as the switching circuit 1 illustrated in FIG. 1. In FIG. 7, elements that are the same as FIG. 1 are given the same reference numerals.

Also, a DC-to-DC converter 32 includes the switching circuit 1, the controller 31, an inductor 33 driven by the switching circuit 1, feedback resistances 34, 35, and a smoothing capacitor 36. The DC-to-DC converter 32 is a DC-to-DC converter that steps down the power supply voltage VIN and outputs an output voltage VOUT.

The controller 31 generates a PWM signal in accordance with an input voltage VFB, and outputs it to the switching circuit 1 as the high-side control signal VH, low-side control signal VL. The controller 31 controls the switching circuit 1 in accordance with the output voltage VOUT of a second end of the inductor 33.

The inductor 33 is connected at first end thereof to the output terminal 18, and is driven by the switching circuit 1. The feedback resistors 34 and 35 are connected in series between the second end of the inductor 33 and the ground terminal 22, and the output voltage VOUT of the second end of the inductor 33 is divided to the voltage VFB and fed back to the controller 31. Also, the smoothing capacitor 36 is connected between the second end of the inductor 33 and the ground terminal 22, and smoothens out the output voltage VOUT.

In this embodiment, the controller 31 generates the high-side control signal VH, low-side control signal VL in accordance with the voltage VFB that detects the output voltage VOUT, and controls the current flowing through the inductor 33 via the switching circuit 1. As a result, it is possible to output the output voltage VOUT which is the power supply voltage VIN stepped down.

The configuration, operation, and effect of this embodiment apart from this are the same as the first embodiment as described above.

In FIG. 7, the configuration of a voltage reducing DC-to-DC converter is illustrated as an example, but also a reversing type DC-to-DC converter that is constituted using the switching circuit constituted from the high-side controller 6a illustrated in FIG. 6 can be constituted. It is also possible to constitute a voltage raising or dropping type DC-to-DC converter by adding a voltage raising type DC-to-DC converter to the second end of the inductor 33 of the DC-to-DC converter 32 illustrated in FIG. 7.

Also, in the first embodiment, a bootstrap type configuration was described as an example in which the power supply voltage Vs2, Vs1 were supplied to the high-side controller 6 and the low-side controller 6a respectively. However, the second intermediate potential terminal 20 is connected to the ground terminal 22, and the first intermediate potential terminal 21 is connected to the high potential terminal 19, so each power supply voltage may be the common power supply voltage VIN.

Also in addition, in each embodiment, the high-side switch 2 has the configuration of a PMOS as an example, but the high-side switch 2 may be an NMOS. In this case, the first voltage V1 and the second voltage V2 each represent the voltage Vgs between the gate and the source of the high-side switch 2 with high-side switch 2 source potential being the reference. Also, the high-side switch 2 and the low-side switch 3 may be BJT, IGBT, or the like. However, if IGBT or BJT or the like are used, the parasitic diode as rectifier 4 is not connected between the low potential terminal 23 and the output terminal 18. Therefore, between the low potential terminal 23 and the output terminal 18 it is necessary to actually connect a rectifier such as a diode or the like to create the same current path.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A switching circuit comprising:
a high-side switch connected between a high potential terminal and an output terminal;
a rectifier connected between the output terminal and a low potential terminal, forward direction of the rectifier being the direction from the low potential terminal to the output terminal; and
a driver supplying a first voltage to a control terminal of the high-side switch in accordance with a high-side control signal and turning the high-side switch on, the driver supplying a second voltage being higher than the first voltage to the control terminal of the high-side switch when the voltage of the output terminal increases to not less than a predetermined value.

2. The circuit according to claim 1, wherein
the driver includes:
a detector comparing the voltage of the output terminal and a reference voltage; and
a high-side controller outputting the first voltage in accordance with the high-side control signal and outputting the second voltage in accordance with the output of the detector.

3. The circuit according to claim 2, wherein the high-side controller operates under a voltage not greater than a power supply voltage supplied between the high potential terminal and the low potential terminal.

4. The circuit according to claim 1, further comprising a low-side switch,
the rectifier being a parasitic diode of the low-side switch connected between the output terminal and the low potential terminal.

5. The circuit according to claim 4, wherein the driver further includes a low-side controller turning the low-side switch on or off in accordance with a low-side control signal.

6. The circuit according to claim 5, wherein the low-side controller operates under a voltage not greater than a power supply voltage supplied between the high potential terminal and the low potential terminal.

7. The switching circuit according to claim 1, wherein the rectifier is a diode, an anode of the diode is connected to the low potential terminal and a cathode of the diode is connected to the output terminal.

8. A DC-to-DC converter comprising:
a switching circuit including:
a high-side switch connected between a high potential terminal and an output terminal;
a rectifier connected between the output terminal and a low potential terminal, forward direction of the rectifier being the direction from the low potential terminal to the output terminal; and
a driver supplying a first voltage to a control terminal of the high-side switch in accordance with a high-side control signal and turning the high-side switch on, the driver supplying a second voltage being higher than the first voltage to the control terminal of the high-side switch when the voltage of the output terminal increases to not less than a predetermined value and
a controller generating the high-side control signal of a PWM signal in accordance with an input voltage.

9. The converter according to claim 8, wherein
the driver includes:
a detector comparing the voltage of the output terminal and a reference voltage; and
a high-side controller outputting the first voltage in accordance with the high-side control signal, and outputting the second voltage in accordance with the output of the detector.

10. The converter according to claim 8, further comprising a low-side switch,
the rectifier being a parasitic diode of the low-side switch connected between the output terminal and the low potential terminal.

11. The converter according to claim 10, wherein the driver further includes a low-side controller turning the low-side switch on or off in accordance with a low-side control signal.

12. The converter circuit according to claim 8, wherein the rectifier is a diode, an anode of the diode is connected to the low potential terminal and a cathode of the diode is connected to the output terminal.

13. The converter according to claim 8, further comprising:
an inductor, a first end of the inductor connected to the output terminal;
a smoothing capacitor connected between a second end of the inductor and the low potential terminal; and
a feedback resistor connected between the second end of the inductor and the low potential terminal, the feedback resistor feeding a voltage back to the controller.

14. The converter according to claim 13, wherein
the driver includes:
a detector comparing the voltage of the output terminal and a reference voltage; and
a high-side controller outputting the first voltage in accordance with the high-side control signal, and outputting the second voltage in accordance with the output of the detector.

15. The converter according to claim 13, further comprising a low-side switch,
the rectifier being a parasitic diode of the low-side switch connected between the output terminal and the low potential terminal.

16. The converter according to claim 15, wherein the driver further includes a low-side controller turning the low-side switch on or off in accordance with a low-side control signal.

17. The converter circuit according to claim 13, wherein the rectifier is a diode, an anode of the diode is connected to the low potential terminal and a cathode of the diode is connected to the output terminal.
